(19) United States
(12) Patent Application Publication
(10) Pub. No.: US 2013/0069507 A1
(43) Pub. Date: Mar. 21, 2013

(54) METHOD AND DEVICE FOR WALL MOUNTING FLAT PANEL MONITOR AND STORING ASSOCIATED AUDIO/VIDEO COMPONENTS

(71) Applicants: James DOWLING, Alton, NH (US); Mark Alan FECTEAU, Alton, NH (US)

(72) Inventors: James DOWLING, Alton, NH (US); Mark Alan FECTEAU, Alton, NH (US)

(21) Appl. No.: 13/613,644

(22) Filed: Sep. 13, 2012

Related U.S. Application Data
(60) Provisional application No. 61/534,993, filed on Sep. 15, 2011.

(51) Int. Cl. H05K 7/20; H05K 5/03; H05K 7/16; H05K 5/02

(52) U.S. Cl. 312/236; 312/223.1; 312/223.2; 312/298

(57) ABSTRACT

A mounting device for a flat panel monitor. The mounting device comprises a front panel and a mating second rear panel for connection with one another to form a housing. At least the front panel has a plurality of mounting apertures therein for securing the housing to a desired flat panel monitor while the rear panel has a mounting mechanism which facilitates attachment of the housing to a desired support surface. An internal recess is formed between the front panel and the rear panel, when assembled with one another, and the internal recess is sized for accommodating and retaining at least one peripheral electronic device therein.

### FIELD OF THE INVENTION

The present invention relates to a novel mounting device for accommodating various electronic components and/or accessories between the rear surface of a television and a desired supporting wall or other structure. More particularly, the present invention relates to attaching and supporting a flat panel monitor to a desired wall and/or other supporting structure with a mounting device which includes an internal recess for supporting and containing associated peripheral components and/or accessories typically used in conjunction with a flat panel monitor.

### BACKGROUND OF THE INVENTION

A variety of different devices are currently available to facilitate mounting and/or supporting a flat TV panel monitor to a wall or some other supporting surface. However, such mounting devices for a flat panel monitor are generally cumbersome to install and typically do not provide space, e.g., an internal cavity or recess, for any peripheral electronic device or accessory, including but are not limited to, a HD box(es), a video network reception box(es) (i.e., Roku), a cable TV satellite box(es), a video game device(s) or console(s), e.g., a PlayStation® console or an X-box® console, a DVD player(s), a cable TV box(es), a Blu-ray player(s), a Wired or Wireless Internet Reception Device, etc.

Conventional devices that attach and support flat panel monitors consist of a panel or bracket that attaches directly to the rear or back surface of the monitor, and a panel or a bracket that attaches directly to a wall or structure with an arm or some other connecting component that pivotally secures these two panels or brackets to one another to allow a pivoting motion thereof. While these devices are adequate in their ability to support a flat panel monitor, they do not address the typical need to accommodate associated components typically used in conjunction with a flat panel monitor, as discussed above. Accordingly, typically an additional wall mounted shelf or floor standing article of furniture is normally required to contain and support such desired peripheral electronic component(s) or accessory. Further, the need for additional, external, accessory containment limits the possible placement location of the flat panel monitor as such additional wall and/or floor space must be considered. Further, a number of wires and cables are generally required in order to connect the flat panel monitor with the peripheral electronic component(s) or accessory and such wiring can be unsightly and/or objectionable.

### SUMMARY OF THE INVENTION

Wherefore, it is an object of the present invention to overcome the above mentioned shortcomings and drawbacks associated with the prior art mounting devices for flat panel monitors.

Another object of the present invention is to provide a mounting device which easily mounts to a rear surface of the flat panel monitor, by utilizing a set of standard VESA mounting holes provided in the mounting device, and is also quickly and easily attached to the mounting surface so that the flat panel monitor can be easily and conveniently mounted by a single installer.

A further object of the present invention is to provide a mounting device in which the space located between opposed surfaces of the panels of the mounting device can be easily adjusted so as to facilitate accommodating different size peripheral electronic device(s), component(s) or accessory within the internal recess formed between the opposed panels of the mounting device or accommodate two or more desired peripheral electronic device(s), component(s) or accessory(ies) therein.

Yet another object of the present invention is to provide a plurality of ventilation openings, holes and/or other apertures within the housing of the mounting device so as to provide adequate cooling ventilation for the desired peripheral electronic device(s), component(s) or accessory to be accommodated within the internal recess of the mounting device and thereby facilitate adequate cooling of each desired peripheral electronic device(s), component(s) or accessory accommodated within the internal cavity and prevent overheating thereof while still providing a plurality of passages for any associated wiring, cable and other electronic connections.

A still further object of the present invention is to form the mounting device from two separate components which are substantially identical to or mirror images of one another so as to minimize associated manufacturing cost while still providing a rigid housing for accommodating the one or more desired peripheral electronic device(s), component(s) or accessory within the internal recess of the mounting device while still securely and permanently retaining the flat panel monitor mounted to the desired wall or other support structure.

Yet another object of the present invention is to provide a mounting device which can be either directly mounted to the wall or other support structure or mounted to a conventional mounting device which is directly mounted to the wall or other support structure and facilitate mounting a flat panel monitor to a desired wall or other support structure.

A further object of the present invention is to provide a mounting device in which the relative spacing between the front and rear panels of the mounting device can be readily altered, with respect to one another, so as to provide the mounting device with a manual adjustment feature which provides the flat panel monitor with a desired tilt of from a few degrees or so (3.5 degrees) to as much as 10° of tilt.

A still further object of the present invention is to provide a mounting device which comprises a housing which is sufficiently closed on five sides thereof and only opened on the top side thereof so as to facilitate access to the internal cavity of the mounting device and the peripheral electronic device(s), component(s) or accessory located therein.

Another object of the present invention is to provide the tabs of the front and rear panels with mating locking features so that adjacent tabs, one overlapped with one another, can interlock with one another and such interlocking feature of the tabs further increases the structural rigidity and integrity of the housing formed by the two mating panels of the mounting device.

Another object of the present invention is to provide a mounting device having L-shaped brackets which are connected to the rear panel of the mounting device and which support a shelf for further peripheral electronic device(s), component(s) or accessory. The shelf is adjustable with respect to the mounting device and enables easy access to the further peripheral electronic device(s), component(s) or accessory.

A further object of the present invention is to provide a mounting device having universal mounting channels so as to facilitate accommodating different sizes of flat panel monitors. The channels further enable lateral adjustment of the flat panel monitor with respect to the mounting device.

The present invention also relates to a mounting device, for a flat panel monitor, comprising a front panel and an opposed and mating second rear panel for connection with one another to form a housing; at least the front panel having a plurality of mounting apertures therein for securing the housing to a desired flat panel monitor; the rear panel having a mounting mechanism which facilitates attachment of the housing to a desired support surface; and an internal recess being formed between the front panel and the rear panel, and the internal recess being sized for accommodating and retaining at least one peripheral electronic device therein.

### BRIEF DESCRIPTION OF THE DRAWINGS

The invention will now be described, by way of example, with reference to the accompanying drawings in which:

FIG. 1 is a perspective view of the mounting device according to the present invention along with a mounting bracket.

FIG. 2 is a perspective view of the mounting device with the individual components separated from one another to illustrate further details of the various components.

FIG. 3 is a front elevation view of the mounting device which illustrates the features of the components.

FIG. 4 is an end view, showing a wall located therebetween, showing two separate installations for flat monitors utilizing the mounting device according to the present invention.

FIG. 5 is an enlarged end view of a section of FIG. 4 which illustrates details of the mounting component.

FIG. 6 is a perspective view showing the mounting device mounted to the rear surface of a flat panel monitor, supported by a base member, for accommodating or storing electronic device(s), component(s) or accessories to be located behind the flat panel monitor.

FIG. 7 is a perspective view of another embodiment of the mounting device according to the present invention showing a mounting device with a shelving unit.

FIG. 8 is a front elevation view of the mounting device which illustrates the features of the mounting device and shelving unit.

FIG. 9 is a side elevation view of the mounting device which illustrates details of the mounting device and shelving unit.

FIG. 10 is a rear elevation view of the mounting device which illustrates the features of the mounting device and shelving unit.

FIG. 11 is a top view of the mounting device which illustrates the mounting device and shelving unit.

FIG. 12 is a bottom view of the mounting device which illustrates further details of the shelving unit.

FIG. 13 is a perspective view of yet a further embodiment of the mounting device comprising the shelving unit and universal mounting channels secured to the mounting device, that is supported on a wall.

FIG. 14 is a front elevation view of the mounting device which illustrates the features of the mounting device, shelving unit and universal mounting channels.

FIG. 15A is a cross sectional diagram of the universal mounting channel viewed along the section line 15A-15A in FIG. 14.

FIG. 15B is cross sectional diagram of the universal mounting channel viewed along the section line 15B-15B in FIG. 14.

FIG. 16 is a side elevation view of the mounting device which illustrates the features of the shelving unit and universal mounting channels secured to the mounting device which is mounted to a wall.

FIG. 17 is a top view of the mounting device which illustrates the features of the shelving unit and universal mounting channels secured to the mounting device which is mounted to a wall.

FIG. 18 is a front elevation view of the mounting device illustrated in FIG. 14, with an alternate orientation of the universal mounting channels.

FIG. 19A is a cross sectional diagram of the universal mounting channel viewed along the section line 19A-19A in FIG. 18.

FIG. 19B is a cross sectional view of the universal mounting channel viewed along the section line 19B-19B in FIG. 18.

FIG. 20 is a side elevation view of the mounting device illustrated in FIG. 18, which shows the universal mounting channels secured to the mounting device in the alternate orientation.

### DETAILED DESCRIPTION OF THE INVENTION

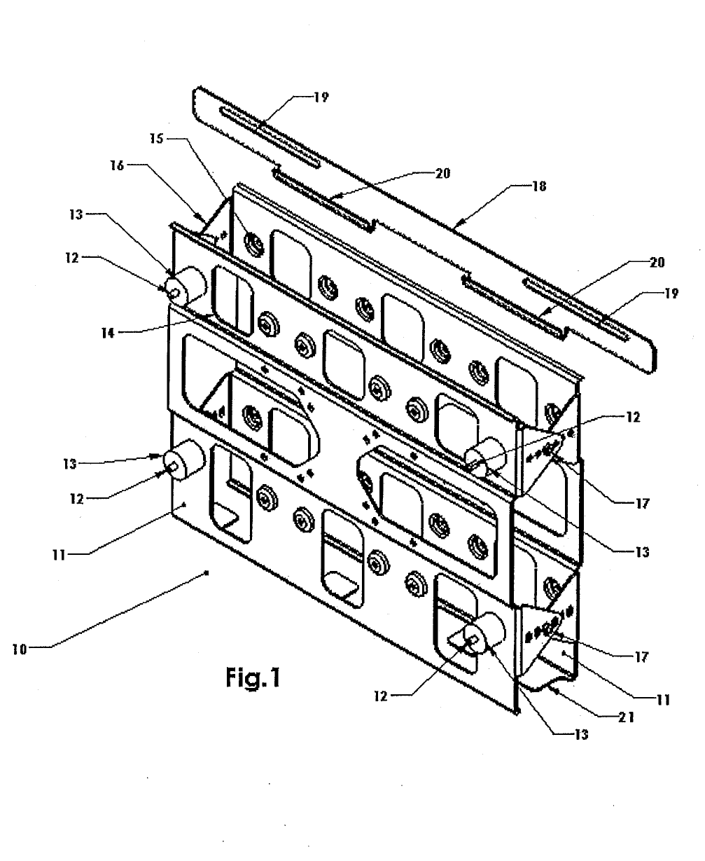

Turning now to FIG. 1, a brief description concerning the various components of the mounting device 2, according to present invention, will now be briefly discussed. As shown therein, the mounting device 2 comprises a generally rigid housing 10 which is formed by mating front and rear panels 11 each of which contains one or more horizontal supports and retaining features 21 which extend from one of the panels 11 toward the other panel and form a base of the housing 10, once the front and the rear panels 11 are assembled with one another as described below, as well as two sets of opposed pairs of end interconnection tabs 16 which are securable to the mating tabs 16 of the other panel 11 by conventional hardware 17 to form a rigid housing 10, as shown in FIG. 1, that will contain a desired peripheral electronic device(s), component(s) or accessory as will be described in further detail below. The horizontal support and retaining features 21 and the mating tabs 16 assist with captively retaining the desired peripheral electronic device(s), component(s) or accessory within the interior recess of the housing 10.

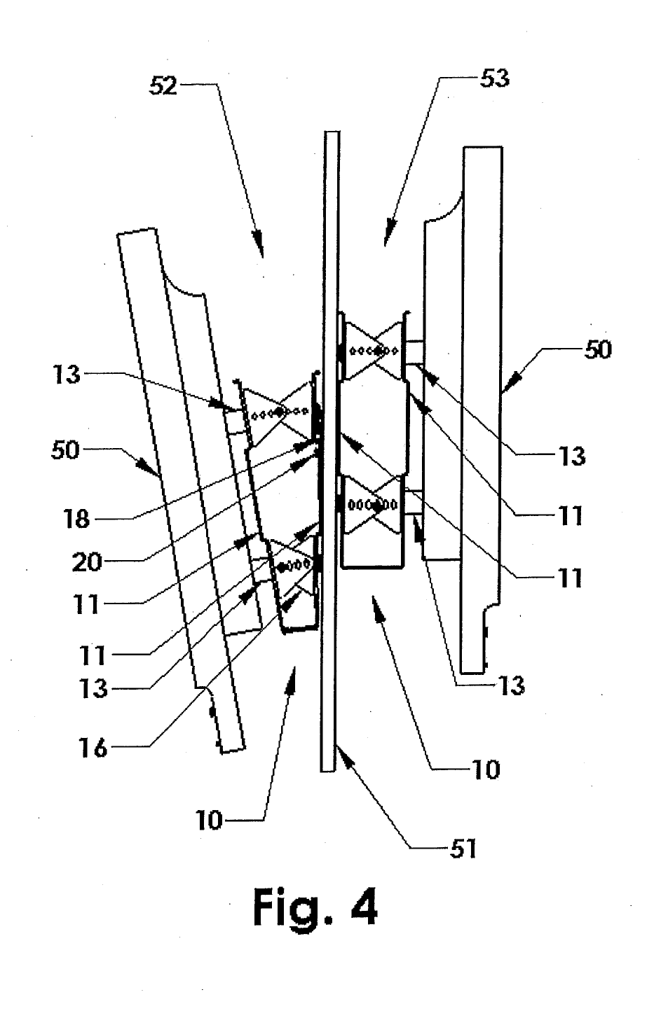

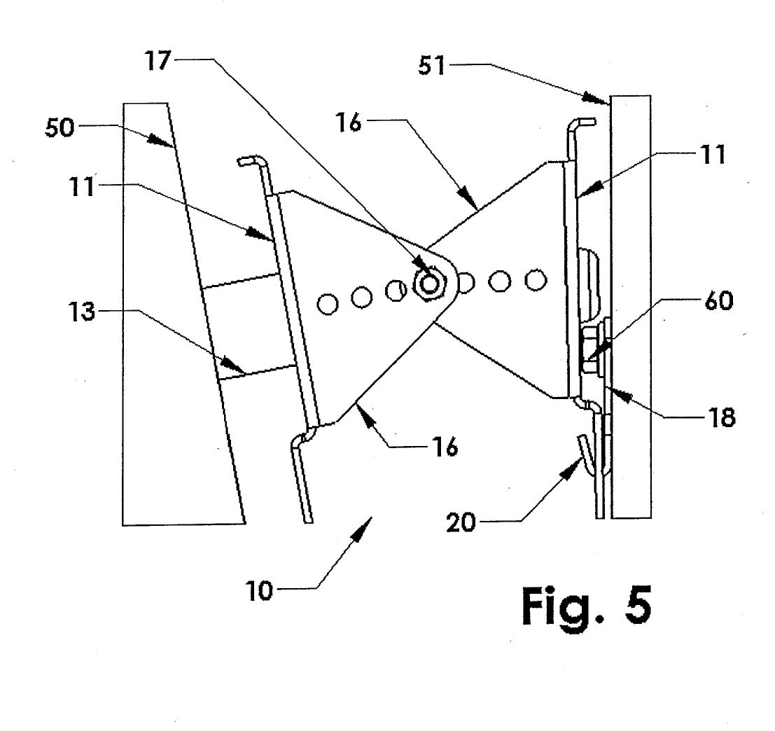

The front and rear panels 11 and the housing 10, when the front and the rear panels 11 are assembled with one another, each have a plurality of ventilation openings 14 which allow any accommodated desired peripheral electronic device(s), component(s) or accessory to be adequately ventilated during use and thereby prevent overheating of the desired peripheral electronic device(s), component(s) or accessory. If necessary or desired, two or more spacers 13 can be attached, between the rear surface of the flat panel monitor 50 and the front surface of the mounting device 2, by utilizing conventional hardware 12 to adequately space the flat panel monitor 50 from the mounting device 2 (see FIGS. 4 and 5) should the need arise to space the housing from the flat panel monitor 50 by a further distance, e.g., to provide additional access to a cable jack(s) and other electrical or cable connection(s) located on a bottom or a rear surface of the flat panel monitor 50.

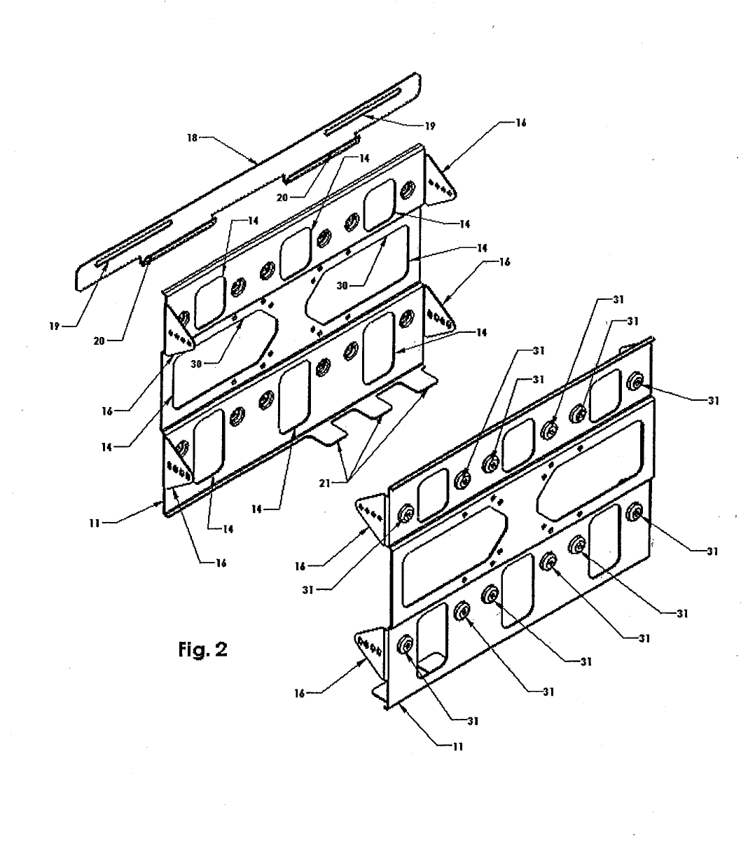

A plurality of mounting holes 15 and 40-45 are provided on at least the front panel 11 for attaching the mounting device 2 to a desired flat panel monitor 50 via conventional fasteners. The rear panel 11 may also be provided with a plurality of spaced apart mounting holes 15 and 40-45 which can be utilized for securing the mounting device 2 to a desired bracket, wall or some other mounting structure 51 via conventional fasteners. Alternatively, a mounting bracket 18 (see FIGS. 1, 2 and 5) can be used for hanging or supporting the mounting device 2, as well as the attached flat panel monitor 50, from the desired wall or some other structure 51. If the mounting bracket 18 is utilized, the mounting bracket 18 is first secured to a desired wall or some other structure 51 utilizing conventional and appropriate hardware which passes through the openings or slots 19 (see FIGS. 1 and 2), provided in the mounting bracket 18, for securing the mounting bracket 18 to the desired wall or some other structure 51. Once the mounting bracket 18 is securely attached to the wall or some other structure 51, the mounting device 2, along with the attached flat panel monitor 50, is then raised and placed over the hook elements 20 of the mounting bracket 18, as shown in FIG. 2. As generally shown in the drawings, each one of the front and the rear panels 11 preferably has a pair of spaced apart hanging opening which are suitably sized for receiving a respective one of the hook elements 20 of the mounting bracket 18. Each of the pair of spaced apart hanging openings has an elongate edge 30 which is sized to receive the hanging element 20 and permit hanging of the mounting device 2 on the mounting bracket 18, in a conventional manner, once the mounting bracket 18 is securely attached to a desired wall or other support structure.

During final installation, the flat panel monitor 50 is raised and the elongate edges 30 of the hanging openings of the rear panel 11 are suitably aligned with the respective hook elements 20 of the mounting bracket 18 for securely but releasably attaching and supporting the flat panel monitor 50 and the mounting device 2 to the mounting bracket 18. Such arrangement allows a single installer to first mount the mounting bracket 2 directly to the rear surface of the flat panel monitor 50 and thereafter mount the mounting bracket 18 directly onto the wall or some other structure 51, at a desired location, and finally hang the flat panel monitor 50 from the mounting bracket 18.

Still referring to FIG. 1, it is to be appreciated that the width of the housing 10 can be adjusted to a desired width which can readily accommodate generally all currently available audio-visual components within the interior recess, formed between the front and the rear panels 11 following assembly thereof with one another to form the rigid housing 10. The width of interior recess, i.e., the spacing of the front and the rear panels 11 from one another, is readily adjustable by suitably positioning holes of the tabs 16 of the front panel 11 with desired holes of the mating tabs 16 of the rear panel 11 and thereafter securing the four sets of overlapped tabs 16 with one another by using conventional hardware 17. Accordingly, the interior width of the cavity can be easily increased or decreased so as to closely accommodate the desired peripheral electronic device(s), component(s) or accessory to be contained within the internal recess of the mounting device 2.

Preferably both the front and the rear panels 11 as well as the mounting bracket 18 are all manufactured from a sufficiently strong and rigid material, such as a metal (e.g., aluminum or steel) or possibly a high strength plastic. Additionally, the spacers 13 can be made from a sufficiently rigid and strong material such as a metal (e.g., aluminum or steel) or possibly a high strength plastic.

Referring now to FIG. 2, the mounting device 2 is shown, before assembly, and comprising the front and the rear panels 11 as well as the associated mounting bracket 18. It is to be appreciated that the mounting bracket 18 may not be utilized in the event that the rear panel 11 of the mounting device 2 is to be secured directly to a conventional bracket or to the wall or some other structure 51. The front and the rear panels 11, when assembled as shown in FIG. 1, together form an enclosure or housing 10 which is suitable for accommodating and captively retaining the desired electronic device(s), component(s) or accessories and defines the internal recess.

The front and the rear panels 11 are attached to one another by placing the tabs 16 on the front panel 11 adjacent to and overlapping the mating tabs 16 of the rear panel 11 (see FIG. 5 for example) and then passing a conventional fastener 17, such as a screw or a bolt, through the aligned apertures of the overlapped tabs 16 to fixedly secure the tabs 16 to one another and thereby form the rigid housing 10 once a mating nut is threaded onto the free end of each of respective screws or the bolts. The tabs 16 are structurally designed so as to support the flat panel monitor 50 as well as the desired peripheral electronic device(s), component(s) or accessory to be accommodated.

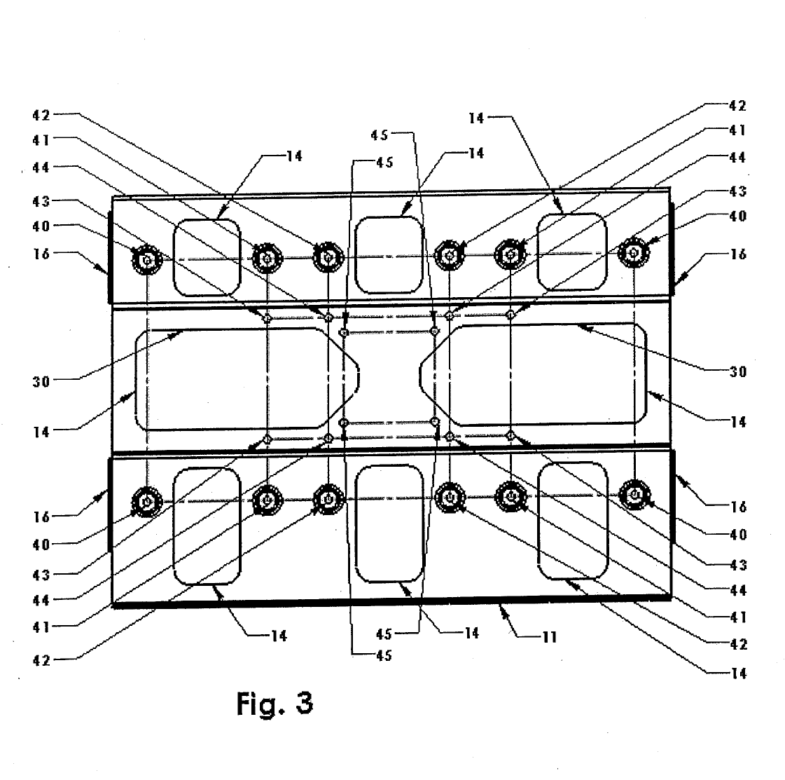

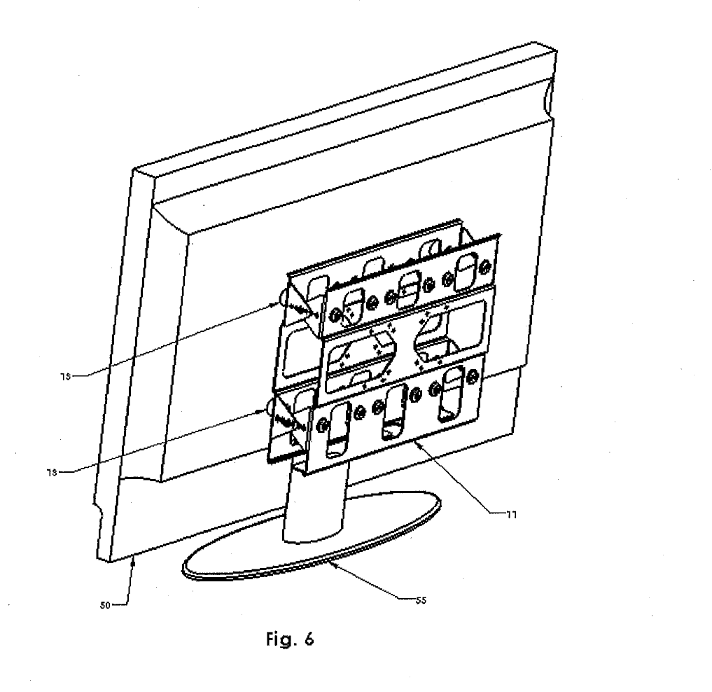

Referring now to FIG. 3, one panel, e.g., the front panel 11, of the mounting device 2 has a variety of attachment possibilities for attaching a variety of different conventional flat panel monitors 50 thereto. In most cases, the flat panel monitor 50 will be mounted to the mounting device 2 by utilizing standardized mounting holes 15 according to the VESA standard. This standard was developed so that flat panel monitor manufacturers can have a standard mounting procedure when wall mount of the flat panel monitor is desired by the end-user. It is to be appreciated that most flat panel monitors also have a base member 55 for supporting the flat panel monitor 50 on a desired floor or furniture. While the present invention is not specifically designed for accommodating or storing electronic device(s), component(s) or accessories to be located behind the flat panel monitor (see FIG. 6), when supported by the base member, the present invention is also applicable for such application. That is, the mounting device 2 can be attached to the rear surface of the flat panel monitor 50, in the manner discussed above, and so that the interior recess can accommodate and thereby results in efficient storage of such electronic device(s), component(s) or accessory behind the flat panel monitor 50.

FIG. 3 illustrates the variety of mounting options that are available of the rear surface of various sizes of flat panel monitors. For example, the set of mounting holes labeled with reference numerals 45 are suitable for an installation using the 75 mm×75 mm VESA standard; the set of mounting holes labeled with reference numerals 44 are suitable for an installation using the 100 mm×100 mm VESA standard; the mounting holes labeled with reference numerals 43 are suitable for an installation using the 200 mm×100 mm VESA standard, the set of mounting holes labeled with reference numerals 42 are suitable for an installation using the 100 mm×200 mm VESA standard, the set of mounting holes labeled with reference numerals 41 are suitable for an installation using the 200 mm×200 mm VESA standard; while the set of mounting holes labeled with reference numerals 40 are suitable for an installation using the 400 mm×200 mm VESA standard.

Referring now to FIG. 4, this drawing illustrates two possible mounting configuration utilizing the mounting device 2 according to the present invention. The right side 53 of that drawing shows the rear panel 11 of the mounting device 2 secured directly to a wall or some other support structure 51 while the front panel 11 of the mounting device 2 is secured to flat panel monitor 50. As shown, four spacers 13 (only two of which are shown in this drawing) provide additional clearance between the rear surface of the flat panel monitor 50 and the mounting device 2 for providing additional room for accommodating any associated wiring and cabling to be located between the flat panel monitor 50 and the desired peripheral electronic device(s), component(s) or accessory to be contained within the housing 10.

During installation, typically the flat panel monitor 50 is arranged, screen side facing downward on the floor or some other assembly surface, and the front panel 11 then is attached to the rear surface of the flat panel monitor 50 utilizing a desired one of the set of mounting holes 15, 40-45, depending upon the size of the flat panel monitor 50. Next, the second panel 11 then is attached to the wall or other support structure 51 utilizing desired one of the mounting holes 15, 40-45. The flat panel monitor 50 is then raised, along with the attached first panel 11, and the tabs 16 of the front and the rear panels 11 are then suitable aligned and overlapped with one another and then conventional fasteners are passed through the aligned opening of the mating tabs 16 to securely attach the front and the rear panels 11 with one another and thereby form the rigid housing 10 which can closely accommodate and sandwich the desired electronic component(s) to be accommodated between the front and the rear panels 11. Lastly, the desired peripheral electronic device(s), component(s) or accessory to be accommodated by the mounting device 2 is then placed within the internal recess and connected to the cable input and the flat panel monitor 50 in a conventional manner.

The left side 52 of the drawing shows the housing 10 hanging from the hook elements 20 of the mounting bracket 18 that was previously secured directly to the wall or other support structure 51 in a conventional manner, e.g., via a plurality of conventional fasteners and mounting components. The first panel 11 is first secured to the flat panel monitor 50, as discussed above, utilizing the spacers 13 to provide additional clearance for any associated wiring and/or cabling between the flat panel monitor 50 and the component or components to be accommodated. Next, the second panel 11 is attached to the first panel 11 to form the housing 10 with the peripheral electronic device(s), component(s) or accessory, to be accommodated by the mounting device 2, located therebetween. The flat panel monitor 50 and the mounting device 2 are then both hung from the mounting bracket 18 as described above.

The left side installation 52 differs from the right side installation 53 in that the spacing of the upper tabs 16 of the housing 10 utilize a different hole spacing than the lower tabs 16 such that the upper portion of the front panel 11 is spaced further away from the rear panel 11 than the lower portion of the front panel 11 which thereby results in an angular tilted installation for the flat panel monitor 50, e.g., provides the flat panel monitor 50 with a desired downward tilt. Alternatively, the upper portion of the front panel 11 can be spaced closer to the rear panel 11 than the lower portion of the front panel 11 which thereby results in the flat panel monitor with a desired upward tilt.

FIG. 5 is an exploded view of from FIG. 4 which illustrates further details of the upper left angled assembly of the housing 10 and the installation of housing 10 utilizing the mounting bracket 18. As shown in this Figure, the mounting bracket 18 is first secured to the wall or other support structure 51 using conventional hardware 60, e.g., a bolt or screw and a mating wall fastener. As shown, a rear panel 11 of the housing 10 hangs from the associated hook elements 20 of the mounting bracket 18 while the front panel Ills attached directly to the flat panel monitor 50 utilizing conventional fasteners as well as four spacers 13. A desired tilt of the housing 10 as well as the flat panel monitor 50 is achieved by aligning desired holes of the adjacent and overlapped tabs 16 with one another and securing the overlapped tabs with one another using appropriate hardware 17. Multiple angles, angled both up and down can be achieved for the flat panel monitor installation.

If desired, the inwardly facing surfaces of the front and the rear panels 11 can each be lined or covered with a soft, compressible material, such as foam, to prevent the mounting device 2 from scratching or otherwise damaging the peripheral electronic device(s), component(s) or accessory to be accommodated by the mounting device 2. Alternatively, the peripheral electronic device(s), component(s) or accessory, to be accommodated by the mounting device 2, can be wrapped or covered with a foam material to protect and avoid scratching or damage thereto.

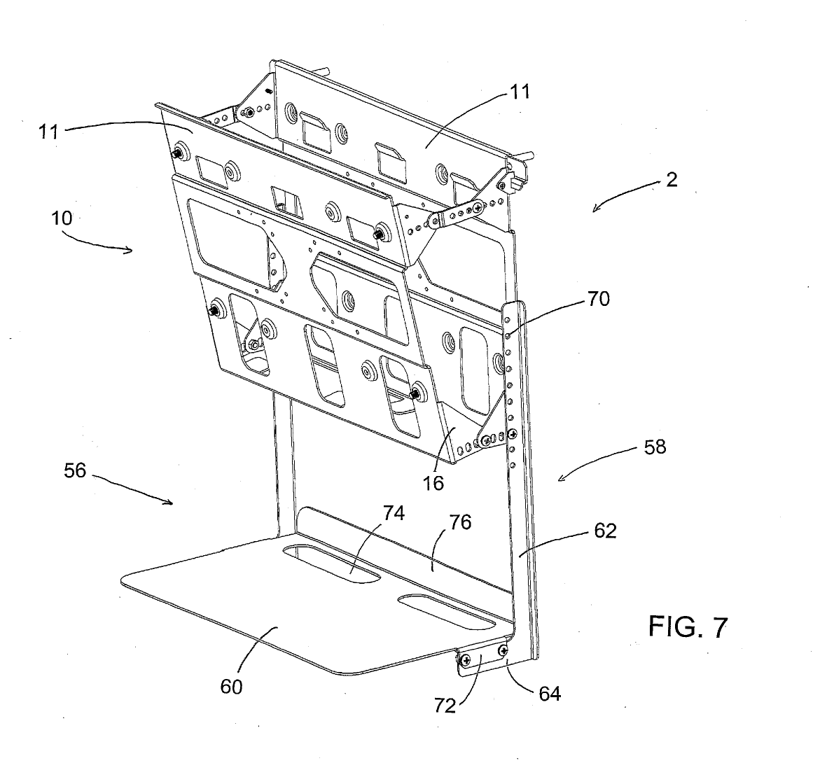

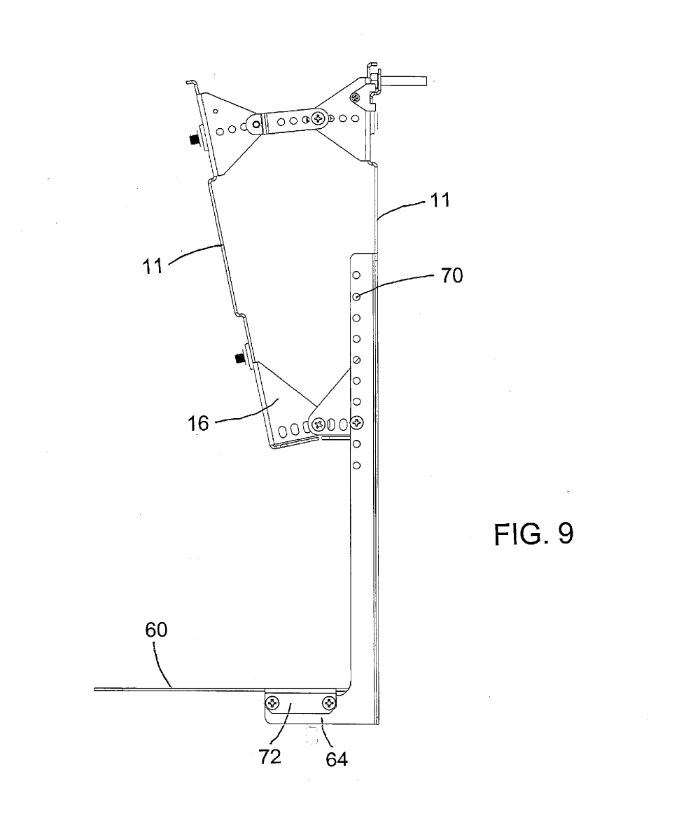

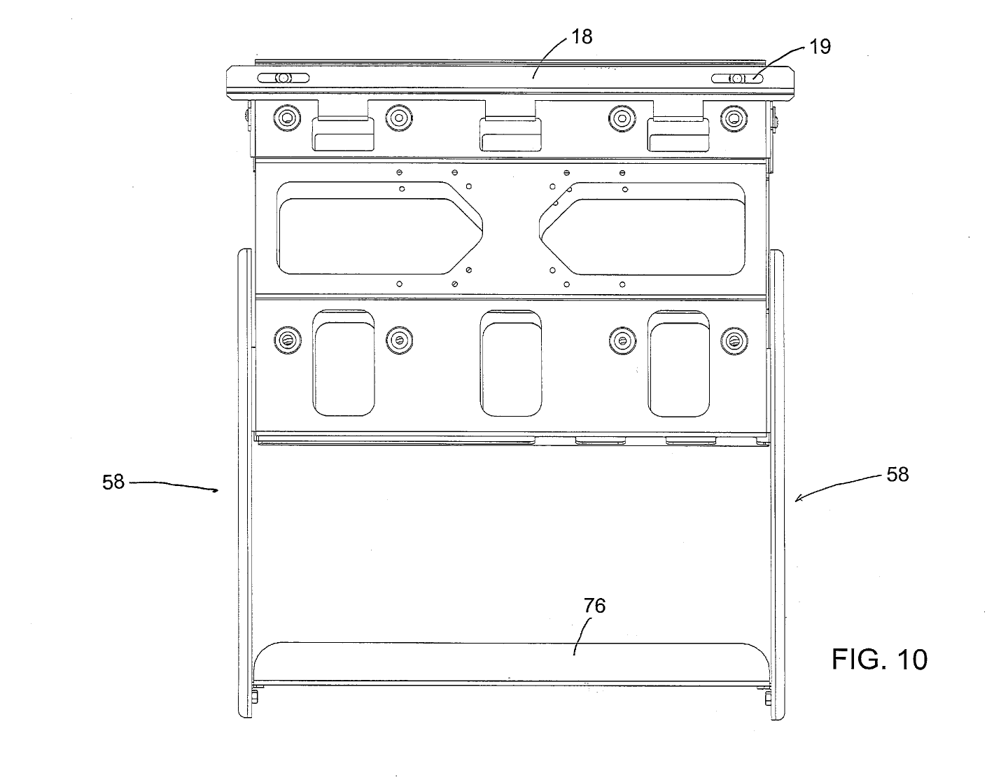

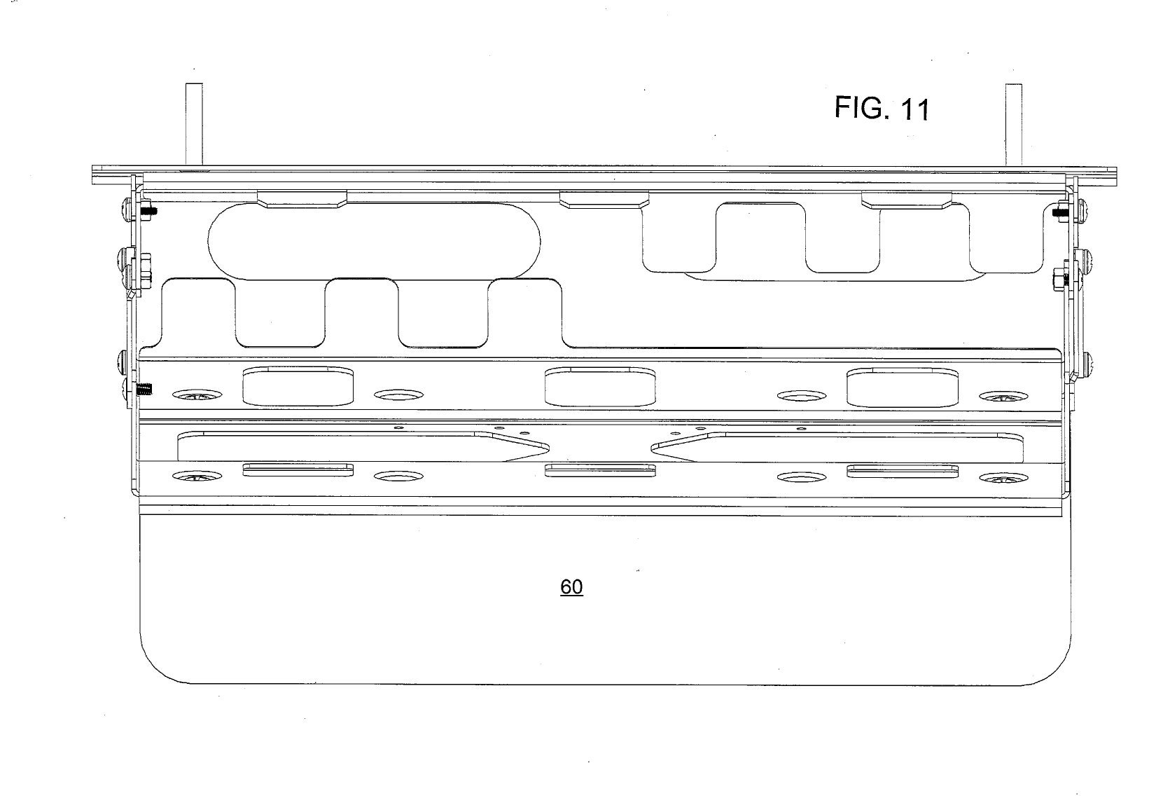

Turning now to FIGS. 7 through 12, an attachment for use with the present invention will now be described.

As can be seen in this embodiment, the attachment comprises a shelving unit 56 which is shown suspended below the housing 10 of the mounting device 2. The shelving unit 56 generally comprises a pair of spaced apart elongate L-shaped brackets 58 and a supported shelf 60. Each of the elongate L-shaped brackets 58 comprises an elongate body 62 and an arm 64. Each elongate body 62 has a backing plate 66 located along a rear surface thereof for abutting against a wall when the mounting device 2 is secured to a wall or some other support structure 51. The upper portion of elongate body 62 of the L-shaped bracket includes a plurality of attachment apertures 70 provided along the length thereof. At least one conventional fastener, e.g., a bolt or screw, passes through a desired one of the apertures 70 and is utilized for securing the upper portion of each elongate body 62 of the L-shaped brackets 58 to one of the lower most connection tabs 16 of the rear panel 11. The plurality of apertures 70 along the L-shaped bracket enable securing the shelving unit 56 to the housing 10 at a number of different relative spacing positions to facilitate supporting one or more other additional peripheral electronic device(s), component(s) or accessory on the shelving unit 56, once suitably suspended below the housing 10 of the mounting device 2.

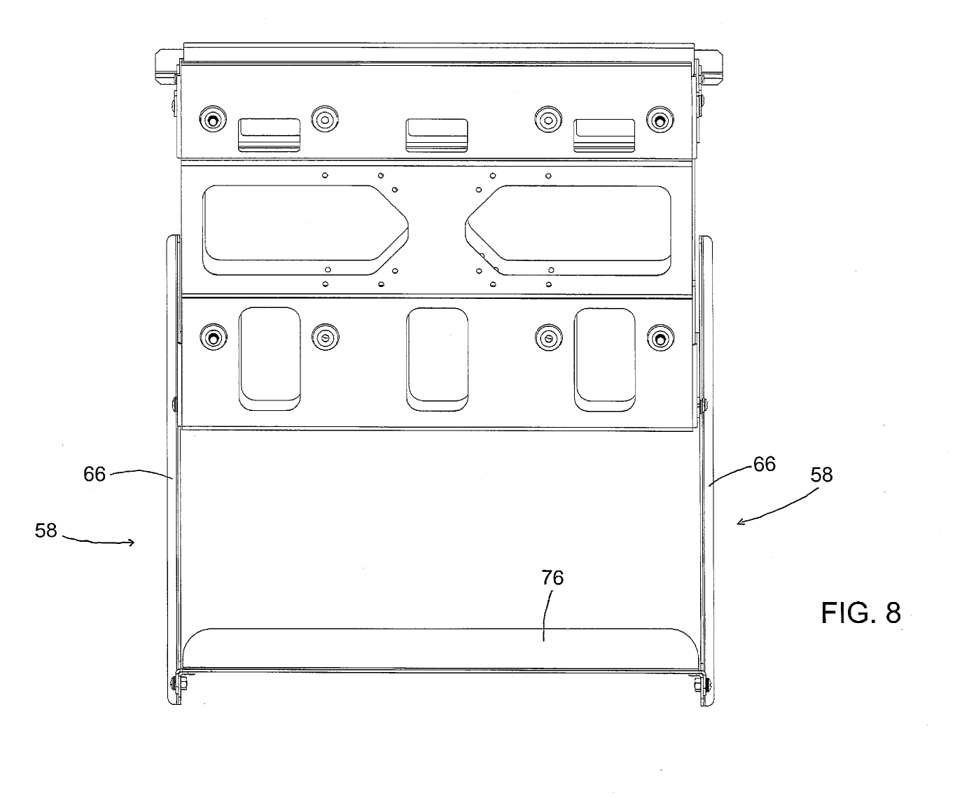

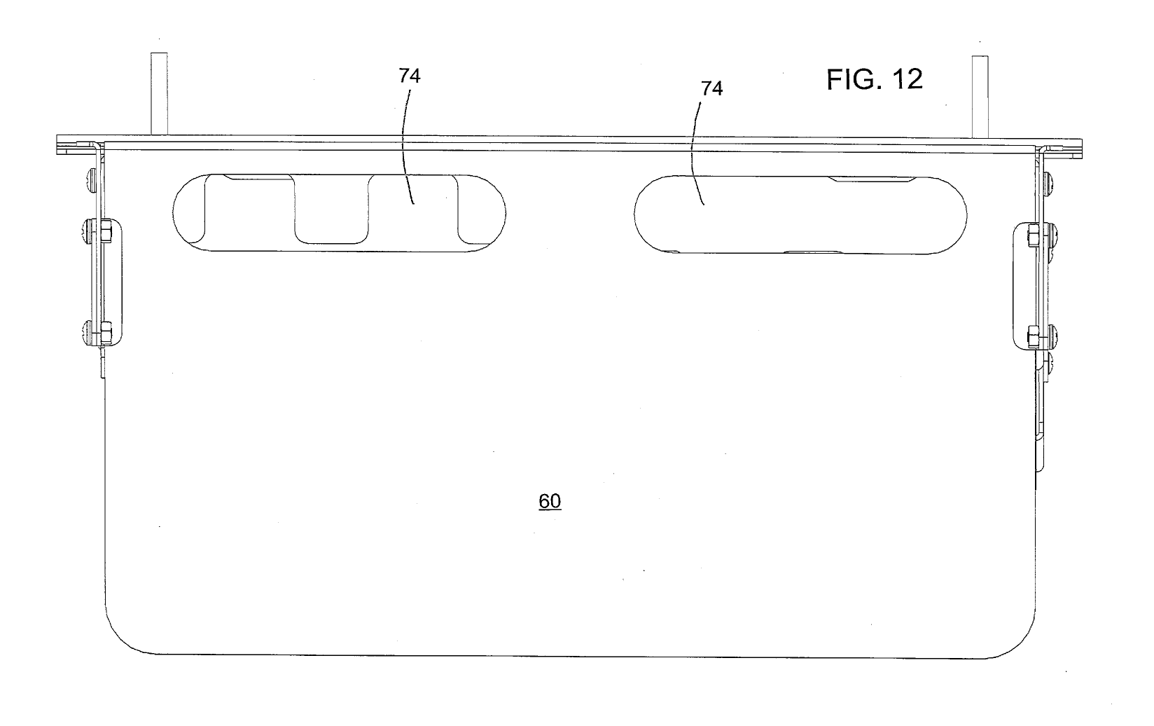

The shelf 60 has a pair of mounting tabs 72. As best shown in FIGS. 7 and 8, the mounting tabs 72 extend over the arms 64 of the L-shaped brackets 58 and are secured to an outwardly facing surface of the arms 64 by conventional fasteners, e.g., a screw or nut and bolt for example. The arms 64 of the L-shaped brackets 58 may also include support tabs (FIG. 12) which engage with a bottom surface of the shelf 60 and provide the shelf 60 with additional support. It is to be appreciated that the shelf 60 can be secured to the L-shaped brackets 58 in an number of different ways. For example, the mounting tabs could be secured to the inside surface of the arms 64 by conventional fasteners or the shelf 60 could simply be welded to the arms 64 without the use of mounting tabs. When the shelf 60 is secured to the L-shaped brackets 58, the shelving unit 56 can be utilized for supporting one or more peripheral electronic device(s), component(s) or other accessory to which frequent and easy access may be desired, such as to exchange desired media, i.e., video games or movies.

The shelf 60 further includes one or more openings and a rear plate. The one or more openings 74 which enable the passage of a cable jack(s) and some other electrical wire or cable connection(s) through the shelf 60. A rear plate 76 of the shelving unit 56 is provided to enhance a rigidity of the shelf 60 and resist bending thereof. In addition, it is to be appreciated that the shelf 60 can be pivotally attached to the pair of L-shaped brackets 58 in order to facilitate pivoting the shelf 60 from an in-use-position, generally shown in FIG. 7, into a stowed not-in-use-position (not shown), without the departing from the spirit and scope of the present invention.

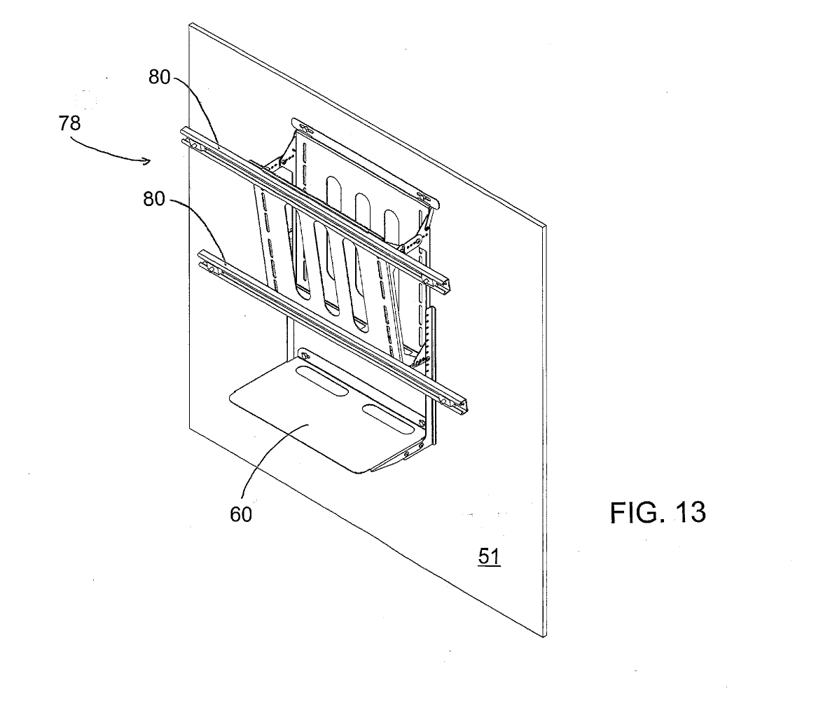

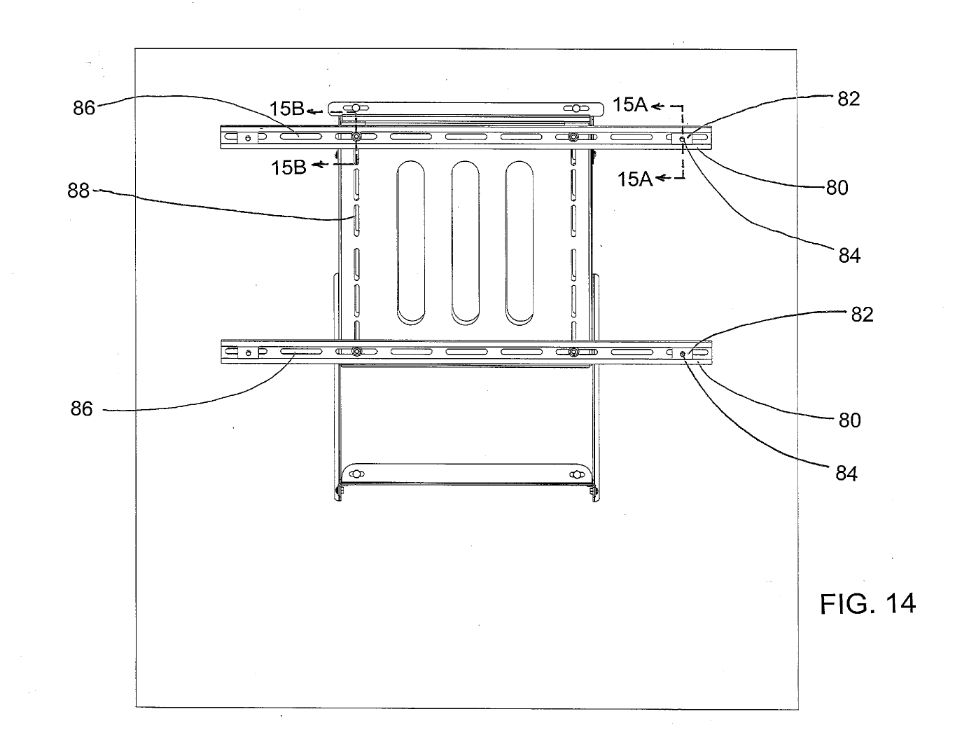

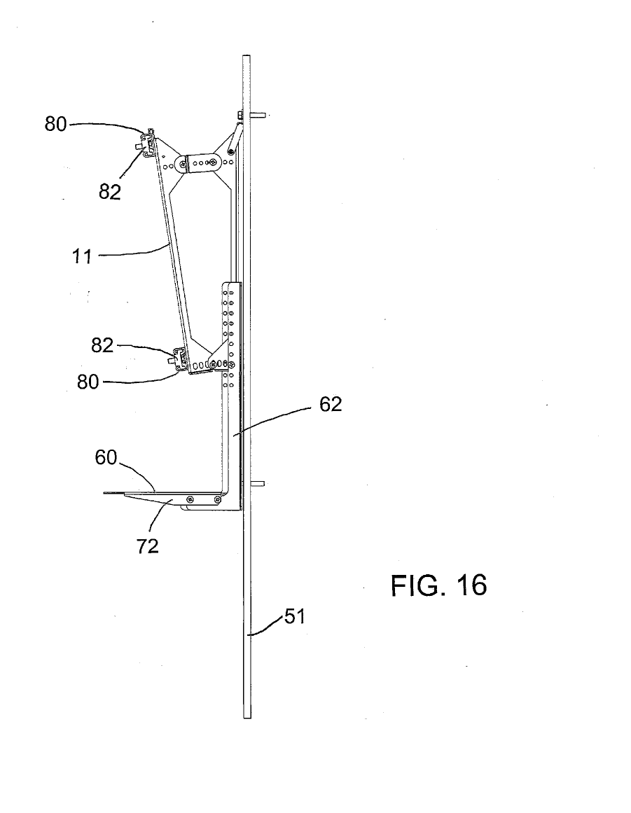

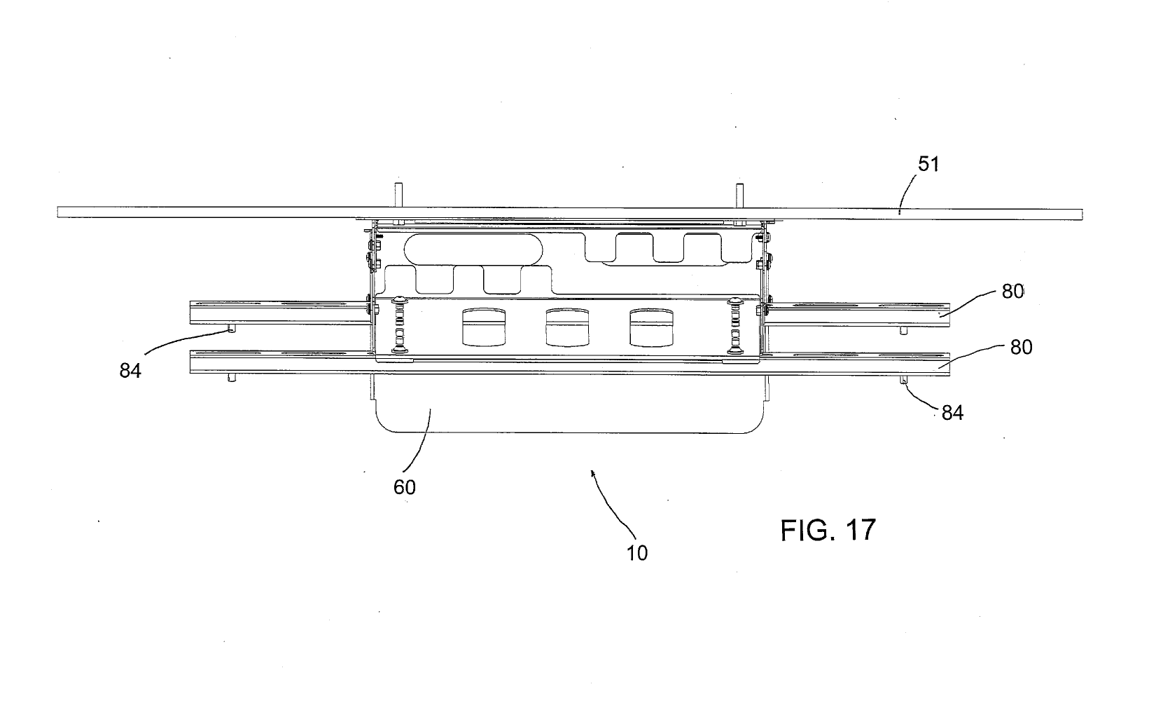

Turning now to FIGS. 13 through 17, an intermediate mount for use with the mounting device 2 of the present invention will now be described. In the following description, the previously described elements with be designated with the same reference numerals.

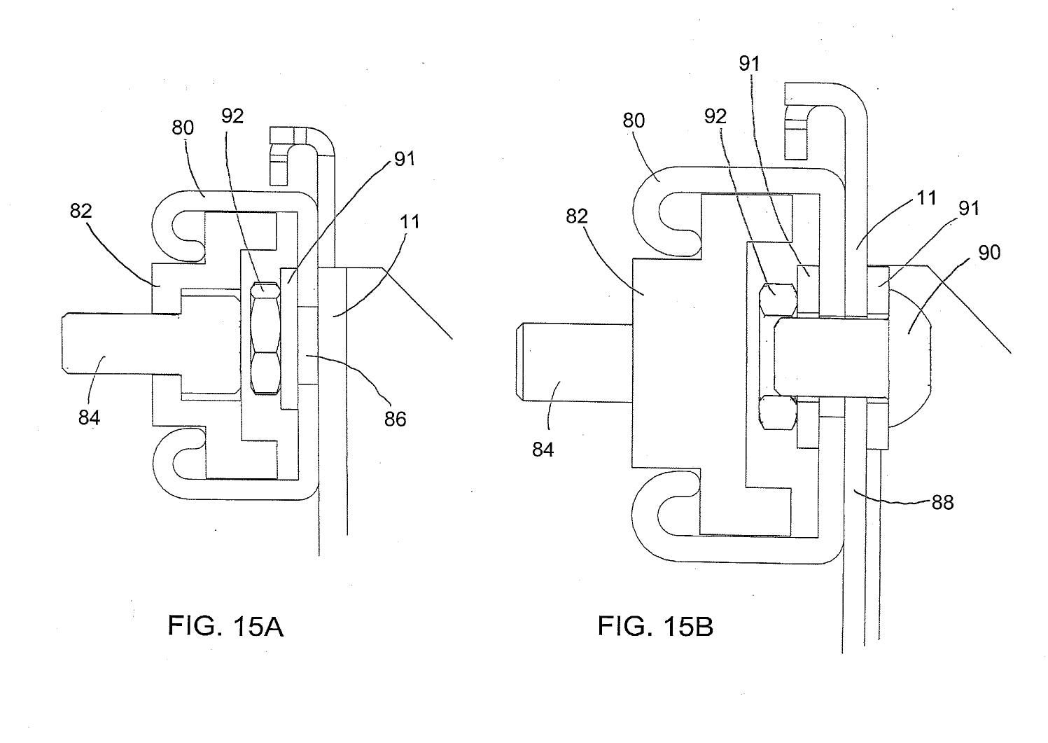

In the previously described embodiment of the mounting device, the flat panel monitor 50 is secured to the front panel 11 of the housing 10 utilizing conventional hardware 12 and possibly four spacers 13. It is also possible to mount the panel monitor 50 to the front panel 11 of the housing 10 via an intermediate mount 78. According to the variation shown in FIGS. 13 through 17, the intermediate mount 78 comprises a separate pair of universal mounting channels 80 and each mounting channel receives a pair of associated mounting nuts 82 and mating fasteners 84, e.g., socket head cap screws. The four mounting nuts 82, two in each mounting channel 80, are rigidly secured to the rear surface of the flat panel monitor 50 by the fasteners 84. The mounting channels 80, as shown in FIGS. 15A and 15B, generally have a C-shaped transverse cross section which captively receives each one of mounting nuts 82 in such a manner that the mounting nuts 82 are retained within the mounting channels 80 but are slidably adjustable therealong.

A rear surface of the mounting channels 80 has a plurality of sequentially arranged elongate horizontal attachment slots 86 provided therein to provide access to facilitate tightening and loosening of the mounting nuts 84 and also facilitate mounting of the mounting channels 80 to the front panel 11 of the housing 10. According to this variation, in order to facilitate connection of the mounting channels 80 to the front surface of the front panel 11 of the housing 10, the front surface of the front panel 11 has a plurality of sequentially arranged elongate vertical attachment slots 88 provided therein. A pair of the plurality of sequentially arranged elongate horizontal attachment slots 86 of the mounting channels 80 engage with, as will be discussed below in further detail, a respective one of the plurality of sequentially arranged elongate vertical attachment slots 88 on the front panel 11 to secure the mounting channels 80 to the housing 10. A respective fastener 90, washers 91 and a mounting nut 92 facilitate attachment of the mounting channels 80 to the front panel 11 of the housing 10. Due to the horizontal and vertical attachment slots 86, 88, the flat panel monitor 50 can readily be adjusted in two dimensions with respect to the front panel 11 of the housing 10 to facilitate an easy and centered attachment thereto.

It should be recognized that because of the adjustability of the mounting nuts 82 within and along the mounting channels 80 as well as the adjustability of the mounting channels 80 with respect to the front panel 11 of the housing 10, via the plurality of sequentially arranged elongate vertical attachment slots 88, the mounting device 2 can readily support monitors of differing formats, shapes and/or sizes. For example, the mounting device 2 can be adjusted to support a square monitor, a monitor that is slightly wider than it is tall (4:3 ratio) or widescreen monitor format that is set at a ratio of 16:9. The mounting device 2 is readily adjustable to support monitors 50 ranging is size from 19 inch diagonals to 80 inch diagonals.

Since the mounting of the flat panel monitor 50 is similar to the previously described embodiment, only the differences between this technique of securing the monitor 50 to the mounting device 2 will be discussed in detail.

In order to secure the flat panel monitor 50 to the front panel 11 of the mounting device 2, the pair of mounting channels 80 are each loosely secured to a desired pair of the plurality of sequentially arranged vertical attachment slots 88 on the front panel 11 so as to be parallel to one another at a distance that is at least roughly equivalent to the spacing between desired vertically upper and vertically lower mounting holes located in the back of the flat panel monitor 50. At this point, the mounting channels 80 are only loosely connected to the housing 10, by the conventional fasteners 90, 92 each engaging with a desired pair of the elongate horizontal attachment slots 86 of the mounting channels 80 and the elongate vertical attachment slots 88 on the front panel 11 (see FIG. 15B) thereby permitting further relative adjustment, as required.

Next, with the flat panel monitor 50 lying, screen side facing downward on the floor or some other assembly surface, the partially assembled mounting device 2 is then placed over the rear surface of the flat panel monitor 50 such that a first one of the mounting channels 80 generally overlies the vertically upper mounting holes while a second one of the mounting channels 80 generally overlies the lower mounting holes in the rear surface of the flat panel monitor 50. Next, each one of the four mounting nuts 82, located within the mounting channels 80, are slid, as necessary, so as to align with a respective desired one of the upper and lower mounting holes in the rear surface of the flat panel monitor 50. Once this is achieved, each one of the respective fasteners 84 are partially tightened.

Once all of the fasteners 82, 84, 90, 92 are partially tightened, the housing 10 and/or the mounting channels 80 are each generally recentered with respect to the rear surface of the flat panel monitor 50. Thereafter, each pair of nuts/fasteners 82, 84 and 90, 92 are securely fastened in a conventional manner. Lastly, the completed assembly can then be affixed to the mounting bracket 18, previously installed to a desired wall or some other structure 51, in the manner described above.

It is to be appreciated that assembly can be performed in the opposite order. That is, the channel members 80 may first be attached to the rear surface of the flat panel monitor 50 and thereafter the channel members 80 can be attached to the front panel 11 of the mounting device 2.

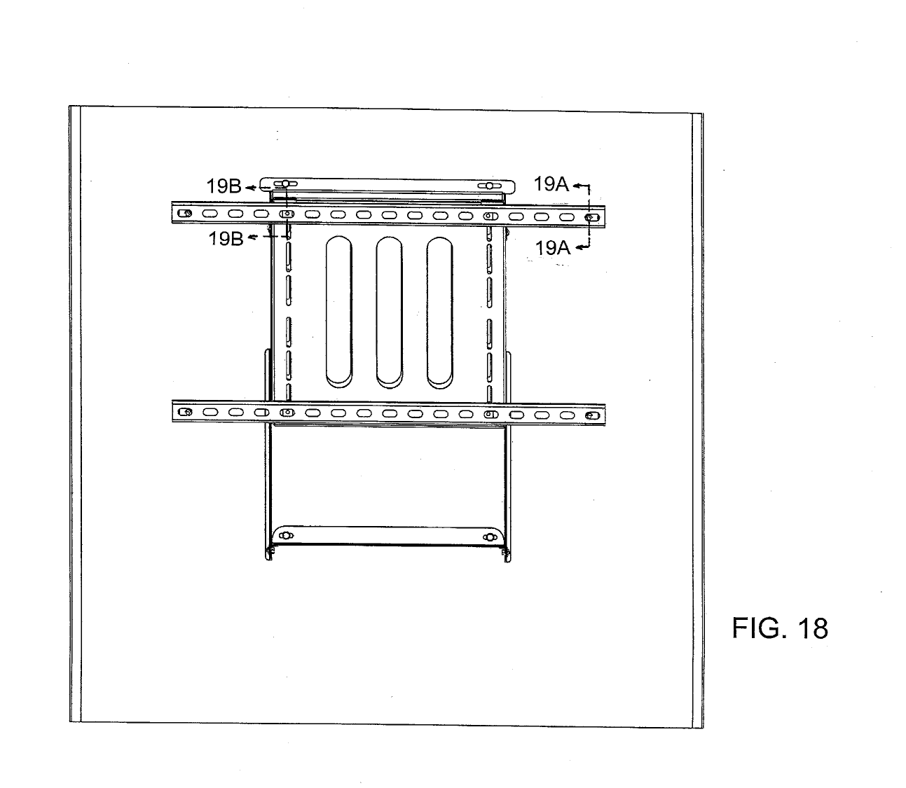

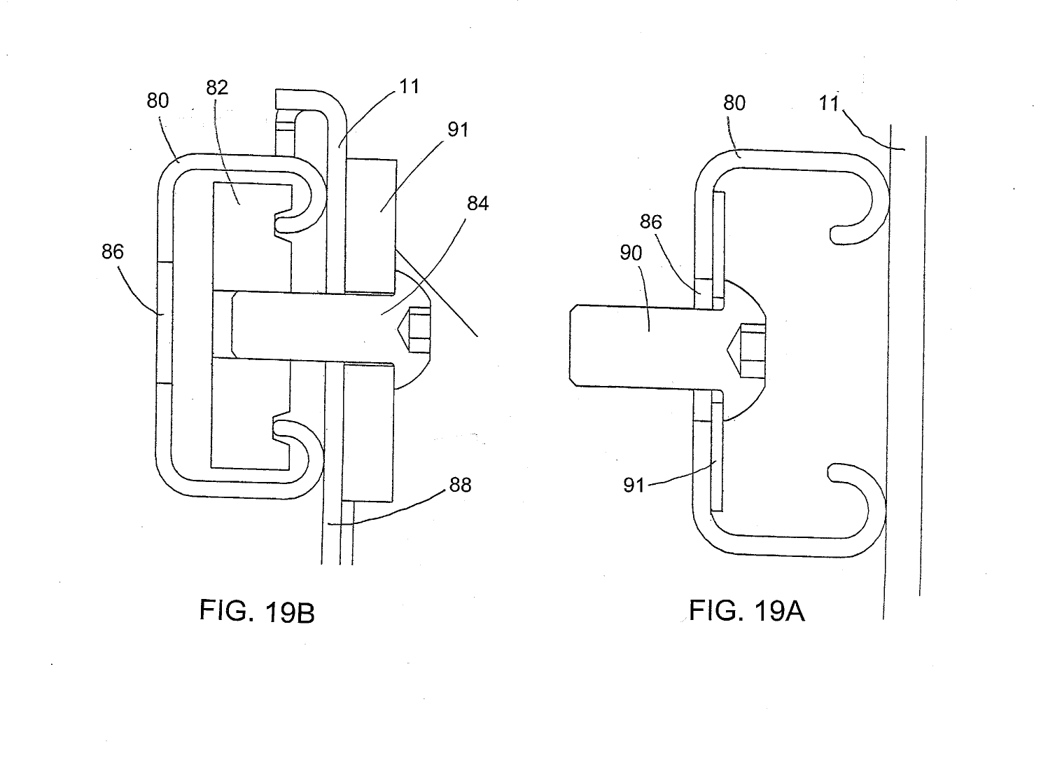

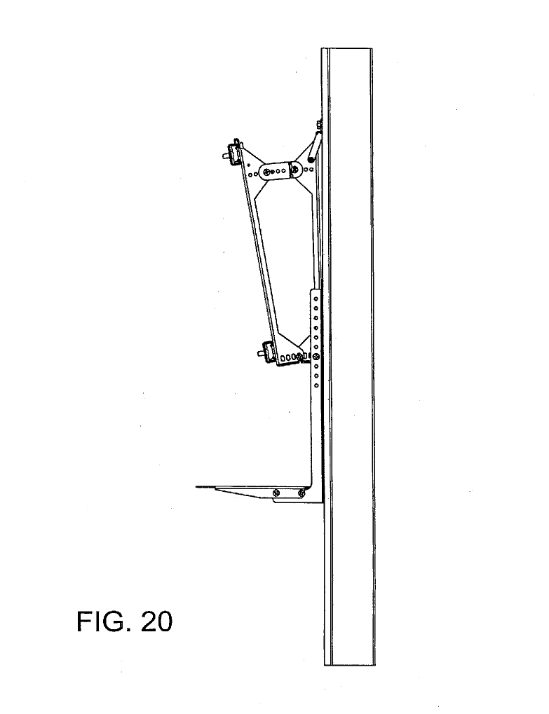

It is also to be appreciated that the mounting channels 80, alternatively, can be rotated 180 degrees with respect to the front surface of the front panel 11 of the housing 10 such that the rear surface of the C-shaped mounting channels 80 are affixed to the rear surface of the flat panel monitor 50. According to this arrangement, as shown in FIGS. 18-20, the four mounting nuts 82, two located in each one of the mounting channel 80, are captively received within the mounting channels 80 and rigidly secured to the front panel 11 of the mounting device 2 by the fasteners 84 (FIG. 19B). In addition, the mounting channels 80, are also rigidly secured to the rear surface of the flat panel monitor 50 by the fasteners 90 (FIG. 19A). In all other respects, the mounting device 2 illustrated in FIGS. 18-20 is substantially similar to the mounting device 2 illustrated in FIGS. 13-17 and thus a further detail description concerning the same is not provided.

It is to be appreciated that the overall length of the mounting channels 80 can vary, depending upon the particular application. For example, a long set of the mounting channels 80 can be utilized for the flat panel monitors 50 that have mounting dimensions greater than 400 mm×400 mm and up to 800 mm×400 mm while a short set of mounting channels 80 can be utilized for the flat panel monitors 50 that have mounting dimensions less than 400 mm×400 mm.

In the above description and appended drawings, it is to be appreciated that only the terms “consisting of” and “consisting only of” are to be construed in the limitative sense while of all other terms are to be construed as being open-ended and given the broadest possible meaning.

Since certain changes may be made in the above described improved mounting device for a flat panel monitor, without departing from the spirit and scope of the invention herein involved, it is intended that all of the subject matter of the above description or shown in the accompanying drawings shall be interpreted merely as examples illustrating the inventive concept herein and shall not be construed as limiting the invention.

Wherefore, I/we claim:

1. A mounting device, for a flat panel monitor, comprising:
a front panel and a mating second rear panel for connection with one another to form a housing;
at least the front panel having a plurality of mounting apertures therein for securing the housing to a desired flat panel monitor;
the rear panel having a mounting mechanism which facilitates attachment of the housing to a desired support surface; and
an internal recess being formed between the front panel and the rear panel, and the internal recess being sized for accommodating and retaining at least one peripheral electronic device therein.

2. The mounting device according to claim 1, wherein the at least one peripheral device is one of a HD box, a video network reception box, a cable TV satellite box, a video game device, a video game console, a DVD player, a cable TV box, a Blu-ray player and a Wired or Wireless Internet Reception Device.

3. The mounting device according to claim 1, wherein the housing has a plurality of openings therein which facilitate ventilation of the at least one peripheral electronic device.

4. The mounting device according to claim 1, wherein the housing is open on at least one side thereof to facilitate access to the internal recess and at least one peripheral electronic device to be located within the housing.

5. The mounting device according to claim 1, wherein the front and the rear panels releasably engage with one another to form the housing and facilitate adjustment of a desired spacing between the front panel and the rear panel of the mounting device from one another and accommodate the at least one peripheral electronic device therebetween in the internal recess.

6. The mounting device according to claim 1, wherein the front and the rear panels releasably engage with one another to form the housing and facilitate adjustment of a desired spacing between the front panel and the rear panel of the mounting device from one another to provide relative tilt between the front panel and the rear panel.

7. The mounting device according to claim 1, wherein a shelving unit engages the rear panel and forms a shelf which supports at least one additional peripheral electronic device thereon and facilitates access to the at least one additional peripheral electronic device.

8. The mounting device according to claim 7, wherein the shelving unit comprises at least two L-shaped brackets, each having an elongate body, a top end of the elongate body releasably engages a respective lateral side of the rear panel, an opposite bottom end of the elongate body comprises an arm that extends normal to the elongate body, a planar shelf plate extends laterally from one of the L-shaped brackets to the other of the L-shaped brackets and is fixed to the arms of the L-shaped brackets to form the shelf which supports the at least one additional peripheral electronic device thereon.

9. The mounting device according to claim 8, wherein each of the elongate bodies of the L-shaped brackets comprises a backing plate which is fixed along at least a portion of length of the elongate body such that when the housing is attached to the desired support surface, the backing plate abuts and supports the L-shaped brackets against the desired support surface.

10. The mounting device according to claim 8, wherein the elongate bodies comprise a plurality of apertures along a length thereof and the lateral sides of the rear panel each comprise an aperture, a fastener passes through the aperture on the lateral surface of the rear panel and one of the apertures along the length of the elongate body to releasably couple the L-shaped brackets to the rear panel.

11. The mounting device according to claim 9, wherein the planar shelf plate comprises at least one passage located adjacent the backing plate which facilitates access to a rear of the at least one additional peripheral electronic device supported on the shelf.

12. The mounting device according to claim 1, wherein mounting channels are secured to the mounting apertures on the front panel of the housing, a plurality of mounting nuts are coupled to a rear surface of the flat panel monitor, the mounting nuts are slidably received within the mounting channels such that the flat panel monitor is slidably secured to the front panel of the housing.

13. The mounting device according to claim 12, wherein the mounting channels are secured to the mounting apertures such that the mounting channels are substantially parallel to each other and extend laterally across the front panel of the housing, the sliding engagement between the mounting nuts and the mounting channels facilitate lateral movement of the flat panel monitor with respect to the housing of the mounting device.

14. The mounting device according to claim 12, wherein the plurality of mounting apertures are elongate apertures that extend vertically along lateral sides of the front panel of the housing, the mounting apertures facilitate adjustably securing the mounting channels at different vertical distances from each other to enable securing flat panel monitors of different sizes to the housing.

15. The mounting device according to claim 14, wherein the mounting channels comprise a plurality of elongate apertures along the length thereof, the elongate apertures of the mounting channels facilitate lateral adjustable engagement of the mounting channels to the front panel of the housing to enable lateral adjustment of the flat panel monitor with respect to the housing of the mounting device.
